(19) United States
(12) Patent Application Publication
(10) Pub. No.: US 2025/0371213 A1
(43) Pub. Date: Dec. 4, 2025

(54) TECHNIQUES FOR SYNTHESIS AND PARAMETRIC OPTIMIZATION OF MECHANICAL SYSTEMS

(71) Applicant: AUTODESK, INC., San Francisco, CA (US)

(72) Inventors: Nastaran SHAHMANSOURI, Toronto (CA); Hyunmin CHEONG, Toronto (CA); Alexander TESSIER, Toronto (CA); Adrian BUTSCHER, Toronto (CA)

(21) Appl. No.: 19/196,676

(22) Filed: May 1, 2025

Related U.S. Application Data
(60) Provisional application No. 63/655,522, filed on Jun. 3, 2024.

(51) Int. Cl. G06F 30/20; G06F 30/17

(52) U.S. Cl. CPC G06F 30/20; G06F 30/17

(57) ABSTRACT

A computer-implemented method for selecting a configuration of a mechanical system that includes a plurality of mechanical building blocks, the method comprising: determining a set of dynamic equations for the mechanical system, wherein each dynamic equation included in the set of dynamic equations corresponds to one mechanical building block included in the plurality of mechanical building blocks; generating a system matrix for the mechanical system based on the set of dynamic equations; and generating a set of parametric values for the set of dynamic equations via parametric optimization, wherein the set of parametric values is associated with a specific configuration of the mechanical system.

### CROSS-REFERENCE TO RELATED APPLICATIONS

This application claims priority benefit of the United States Provisional patent application titled, “MODULAR TECHNIQUES FOR KINEMATIC MECHANISM SYNTHESIS AND PARAMETRIC OPTIMIZATION,” filed on Jun. 3, 2024 and having Ser. No. 63/655,522. The subject matter of this related application is hereby incorporated herein by reference.

### BACKGROUND

### Field of the Various Embodiments

The various embodiments relate generally to computer science and complex software applications, and, more specifically, to techniques for synthesis and parametric optimization of mechanical systems.

### Description of the Related Art

Mechanism design is an important technique in the field of mechanical engineering, and plays a significant role in the development and innovation of machines and mechanical systems. Generally, mechanism design involves the conceptualization, analysis, and optimization of machines and mechanical systems to achieve a desired functionality or output.

Mechanism design can be a complex and open-ended process. First, design engineers oftentimes face complex problems with conflicting goals, such as minimizing the weight while maximizing the strength or durability of a mechanical system or device. Thus, changes to a mechanical system to enhance performance with respect to one design goal can reduce the performance of that system with respect to another design goal. In addition, when mechanical inputs to a mechanical system (e.g., rotation at a specific rotational speed of a shaft)—along with a target mechanical output from the mechanical system (e.g., motion of a component along a prescribed path, an output torque, etc.)—are specified, many different combinations of mechanical devices (e.g., gears, shafts, linkages, etc.) can be linked together as a proposed mechanical system. Further, each such proposed mechanical system can be implemented in a nearly infinite number of possible configurations, given the physical attributes of each mechanical device (e.g., link length, gear-tooth radius, pulley radius, worm-gear diametral pitch, etc.) can be varied through a continuum of different values. Thus, while mechanism design can be a highly beneficial technique in mechanical system design, selection of a more effective mechanical system from the expansive set of potentially feasible mechanical systems can be problematic.

Simplifying the process of mechanism design has been extensively explored. For example, to provide a more structured approach in the conceptual phase of mechanical design, the concept of kinematic building blocks has been developed. Kinematic building blocks—also referred to as kinematic functional units-qualitatively represent the types of motion a particular mechanical device included in a mechanical system can perform, such as rotation, translation, etc. For instance, a pulley-belt mechanism can be abstractly instantiated as a kinematic building block that receives an input torque and produces an output torque, while a worm-gear mechanism can be instantiated as a kinematic building block that receives an input rotation of a worm-gear shaft and produces an output rotation of a spur gear. Thus, kinematic building blocks enable designers to assemble a group of kinematically-compatible mechanical devices into a mechanical system that produces a targeted mechanical output.

Despite the foregoing benefits, the use of kinematic building blocks cannot offer a mechanical designer any insight into how effectively a particular group of assembled mechanical devices can generate a targeted mechanical output, for example, with respect to one or more performance criteria. Instead, mechanical designers are oftentimes forced to select a final configuration of a mechanical system by trial and error, which can be time-consuming and can result in overlooking more effective configurations of that mechanical system. Furthermore, such trial-and-error approaches are generally not suitable for comparing the overall effectiveness with which different mechanical systems can generate the targeted mechanical output.

As the foregoing illustrates, what is needed in the art are more effective techniques for determining desirable configurations for mechanical systems.

### SUMMARY

A computer-implemented method for selecting a configuration of a mechanical system that includes a plurality of mechanical building blocks, the method comprising: determining a set of dynamic equations for the mechanical system, wherein each dynamic equation included in the set of dynamic equations corresponds to one mechanical building block included in the plurality of mechanical building blocks; generating a system matrix for the mechanical system based on the set of dynamic equations; and generating a set of parametric values for the set of dynamic equations via parametric optimization, wherein the set of parametric values is associated with a specific configuration of the mechanical system.

At least one technical advantage of the disclosed techniques relative to the prior art is that the disclosed techniques enable automated parametric optimization of a multi-device mechanical system with respect to one or more design objectives. As a result, for a mechanical system that includes an assembly of multiple kinematically linked mechanical devices, the effectiveness of a plurality of different configurations of the assembly can be quantitatively determined. The effectiveness of each of the different configurations can be determined based on multiple design objectives, and, in some embodiments, multi-disciplinary design objectives. As a result, for a mechanical system that addresses a complex and multi-disciplinary mechanical problem, the disclosed techniques can determine a configuration that corresponds to a global (multi-disciplinary) optimum. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a mechanical system optimization engine, according to various embodiments.

FIG. 2A is a schematic illustration of a pulley-belt mechanism that can be a mechanical building block (MBB) referenced in the MBB library of FIG. 1, according to various embodiments.

FIG. 2B illustrates entries in the MBB library of FIG. 1 that are associated with the pulley-belt mechanism MBB of FIG. 2A.

FIG. 3A is a schematic illustration of a spur-gear mechanism that can be an MBB referenced in the MBB library of FIG. 1, according to various embodiments.

FIG. 3B illustrates entries in the MBB library of FIG. 1 that are associated with the spur-gear mechanism MBB of FIG. 3A.

FIG. 4A is a schematic illustration of a worm-gear mechanism that can be an MBB referenced in the MBB library of FIG. 1, according to various embodiments.

FIG. 4B illustrates entries in the MBB library of FIG. 1 that are associated with the worm-gear mechanism MBB of FIG. 4A.

FIG. 5A is a schematic illustration of a slider mechanism that can be an MBB referenced in the MBB library of FIG. 1, according to various embodiments.

FIG. 5B illustrates entries in the MBB library of FIG. 1 that are associated with the slider mechanism MBB of FIG. 5A.

FIG. 6A is a schematic illustration of a L-linkage pivot that can be an MBB referenced in the MBB library of FIG. 1, according to various embodiments.

FIG. 6B illustrates entries in the MBB library of FIG. 1 that are associated with the L-linkage pivot MBB of FIG. 6A.

FIG. 7A is a schematic illustration of a four-bar-linkage that can be an MBB referenced in the MBB library of FIG. 1, according to various embodiments.

FIG. 7B illustrates entries in the MBB library of FIG. 1 that are associated with the four-bar-linkage MBB of FIG. 7A.

FIG. 8 sets forth a flowchart of method steps for selecting a configuration of a mechanical system that includes a plurality of MBBs, according to various embodiments.

FIG. 9A is a schematic diagram of a mechanical system that can be optimized, according to various embodiments.

FIG. 9B is a block diagram illustrating the MBBs that are kinematically linked together to form the mechanical system of FIG. 9A.

FIG. 10 is a block diagram of a computing device configured to implement one or more aspects of the various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

### System Overview

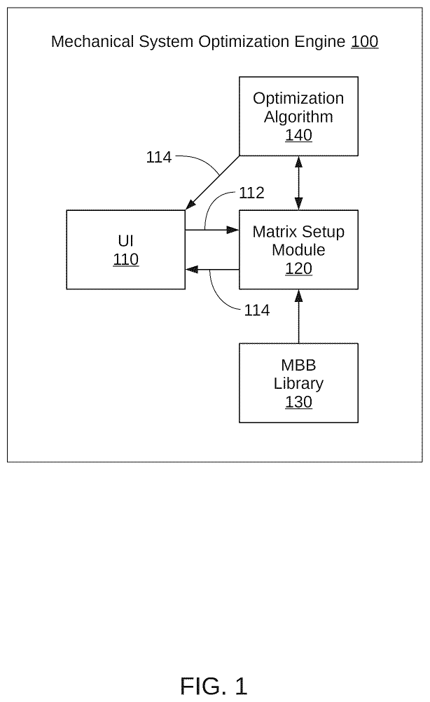

FIG. 1 illustrates a mechanical system optimization engine 100, according to various embodiments. Mechanical system optimization engine 100 is configured to generate a configuration of a mechanical system that includes multiple kinematically linked mechanical devices and addresses a mechanical problem. Thus, given an assembly of kinematically linked mechanical devices (including, for example, one or more pulleys, worm gears, spur gears, linkages, and/or the like) and one or more design objectives (e.g., minimum system weight, minimum system volume, maximum normal force exerted on an article, maximum produced torque, and/or the like), mechanical system optimization engine 100 can determine a set of values for the design variables of each mechanical device. For example, mechanical system optimization engine 100 can provide values for design variables, such as link length, gear-tooth radius, pulley radius, worm-gear diametral pitch, screw pitch angle, and the like, that correspond to a configuration of a mechanical system that has high or optimal performance with respect to the one or more design objectives. In some embodiments, mechanical system optimization engine 100 can generate a high- or optimal-performance configuration of a mechanical system that addresses a multi-disciplinary mechanical problem, in which two or more design objectives are drawn from different relevant disciplines and are considered simultaneously during optimization. In the embodiment shown in FIG. 1, mechanical system optimization engine 100 includes a user interface 110, a matrix set-up module 120, an optimization algorithm 140, and a mechanical building block (MBB) library 130.

User interface (UI) 110 enables a user to provide inputs 112 to and view or otherwise receive outputs 114 from mechanical system optimization engine 100, for example via suitable input/output (I/O) devices. For example, in some embodiments, UI 110 includes a graphical user interface (GUI) that is displayed via a suitable display device. Alternatively, or additionally, in some embodiments, UI 110 includes a command-line interface that enables a user to interact with mechanical system optimization engine 100 via typed commands and text-based output. In some embodiments, the command-line interface can be a terminal window or other text-based window within a GUI. Thus, in some embodiments, inputs 112 and/or outputs 114 can be graphical and/or text-based.

Inputs 112 can include one or more indicators corresponding to the specific MBBs to be included in a mechanical system to be optimized by mechanical system optimization engine 100, for example as defined by a user. Alternatively, or additionally, in some embodiments, inputs 112 can include one or more indicators corresponding to a specific kinematic coupling between two MBBs included in the mechanical system of interest, for example as defined by a user. Alternatively or additionally, in some embodiments, inputs 112 can include values for certain design variables of each MBB or component of each MBB included in the mechanical system that are fixed, such as link length, gear-tooth radius, pulley radius, worm-gear diametral pitch, cross-sectional area of a component of the MBB, density and/or other materials properties of a component of the MBB, and the like. Alternatively, or additionally, in some embodiments, inputs 112 can include initial values for particular design variables of each MBB or component of each MBB included in the mechanical system. In such embodiments, subsequent optimization performed by mechanical system optimization engine 100 can begin using the initial values for the particular design variables. Alternatively or additionally, in some embodiments, inputs 112 can include values corresponding to certain design constraints for the mechanical system of interest, such as maximum or minimum values for certain state variables of the mechanical system of interest (e.g., rotational or translational velocity of a joint or link, displacement of a joint along a particular axis of translation, etc.), maximum or minimum values for certain design variables of the mechanical system of interest, and/or one or more values indicating specific design objectives (e.g., weight, tensile strength, deflection, and the like) that define the objective function for the optimization process performed by mechanical system optimization engine 100. Generally, the objective function is associated with a specific design requirement or combination of design requirements.

Outputs 114 can include graphical and/or text-based information associated with one or more configurations of the mechanical system of interest. For example, in some embodiments, outputs 114 can include a graphical or text-based representation of an optimal or high-performing configuration of the mechanical system of interest that is generated by mechanical system optimization engine 100. In such embodiments, the configuration can include values for the various design variables determined by mechanical system optimization engine 100. Alternatively, or additionally, outputs 114 can include the performance of the optimal or high-performing configuration with respect to the objective function, for example via a score. In some embodiments, outputs 114 can include graphical and/or text-based information associated with multiple configurations of the mechanical system of interest, such as the five highest-scoring configurations generated by mechanical system optimization engine 100 and the associated design variable values.

MBB library 130 stores information associated with a plurality of MBBs that can be combined to form different mechanical assemblies. Generally, each MBB represented in MBB library 130 can be kinematically linked to one or more other MBBs to form a mechanical assembly or system that produces a specific mechanical output in response to a specific mechanical input. Examples of such MBBs include, without limitation, a pulley belt, various gears (e.g., a spur gear, a worm gear, a helical gear, a rack and pinion, a bevel gear, a screw gear, a miter gear, and the like) a shaft, a slider, various linkages, (e.g., an L-linkage pivot, a four-bar linkage, a reverse-motion linkage, a push-pull linkage, a parallel-motion linkage, a bell-crank linkage, and the like), various slider-rockers, a lever, a cam and follower, and the like.

For each MBB represented in MBB library 130, MBB library 130 stores a governing dynamic equation (or in some instances a system of multiple dynamic equations) and a list of applicable design variables and state variables referenced in the governing dynamic equation. In addition, for each MBB represented in MBB library 130, MBB library 130 stores the mechanical input the MBB receives when in operation and a target mechanical output from the mechanical system when in operation. Examples of such mechanical inputs include, without limitation, rotation at a specific rotational speed of an input shaft or gear, translation of a component (link or joint) of the MBB in a particular direction, an input torque, and the like. Examples of target mechanical outputs include, without limitation, rotation at a specific rotational speed of an output shaft or gear, translation of a component of the MBB in a particular direction, an output torque, motion of a component of the MBB along a prescribed path, and the like.

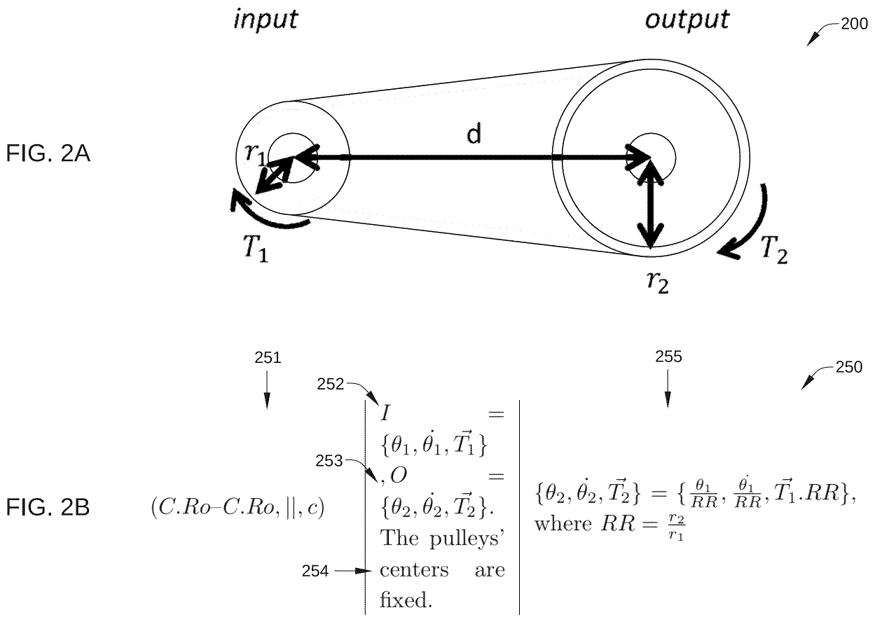

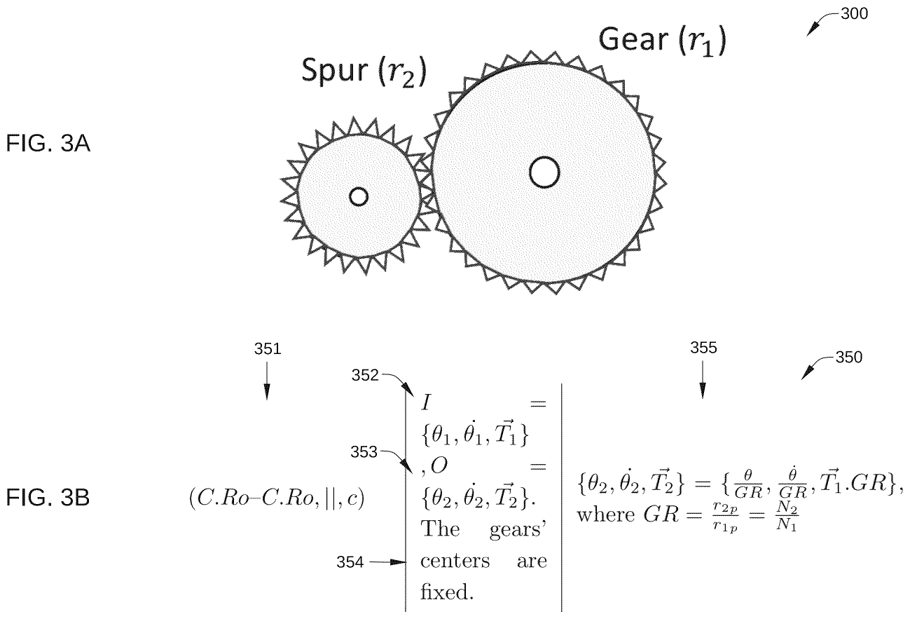

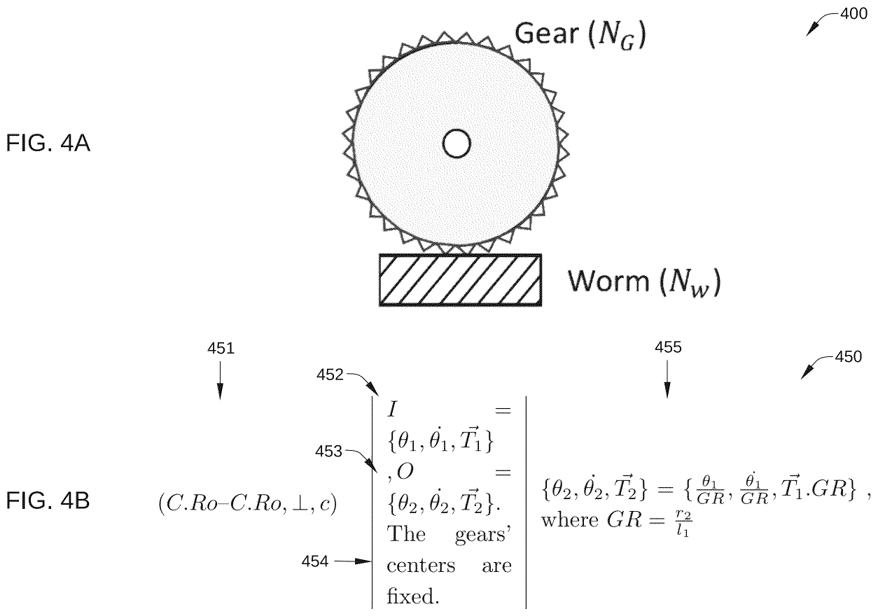

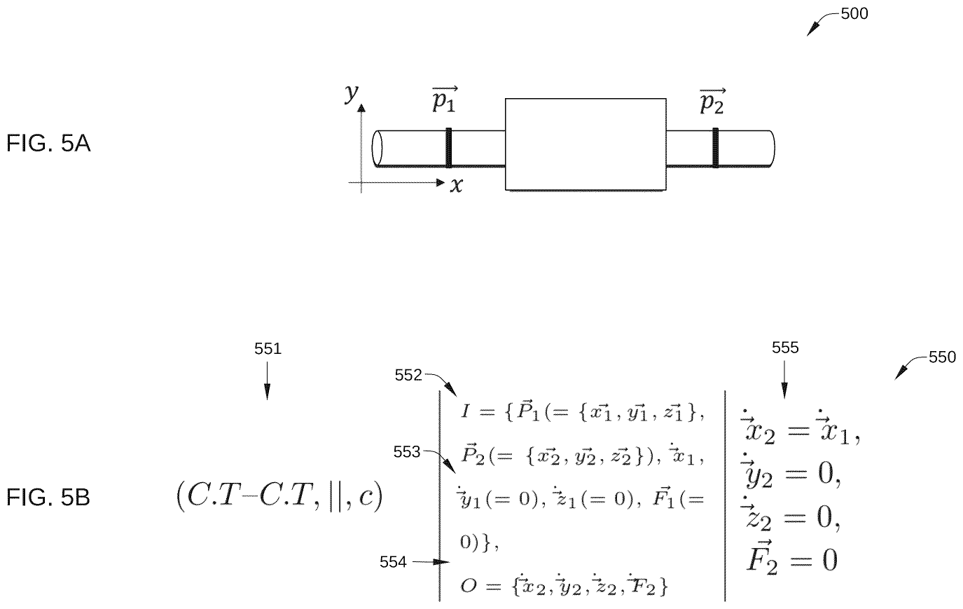

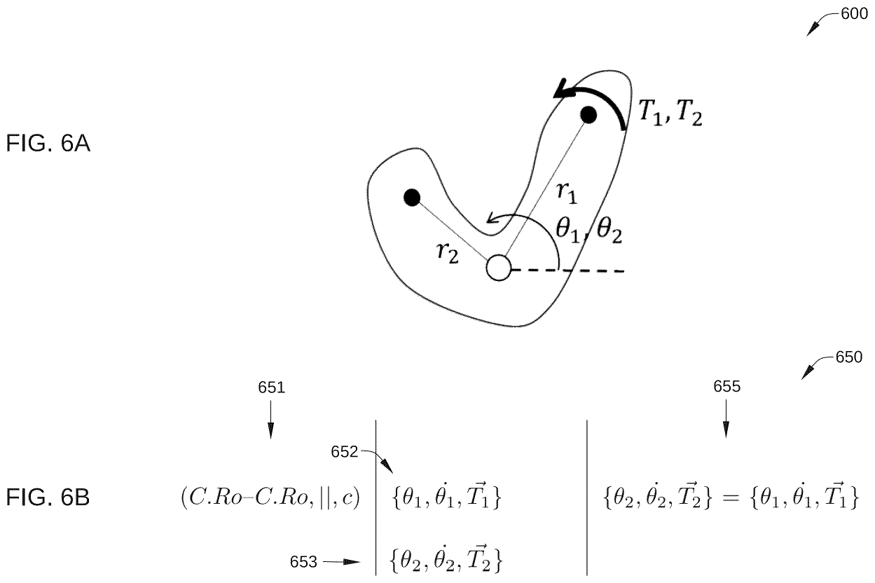

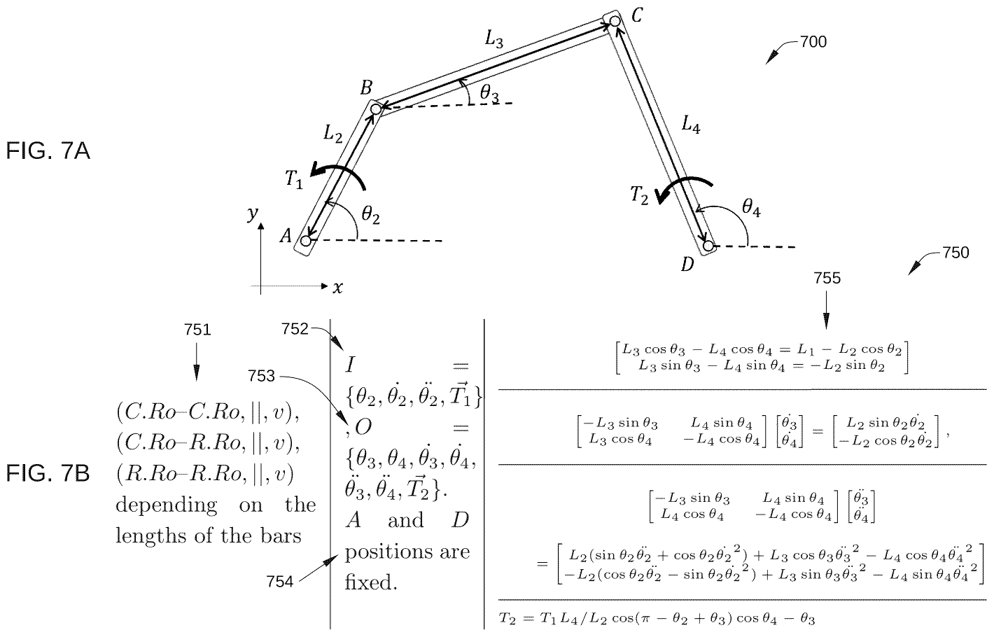

Example embodiments of MBB entries stored in MBB library 130 for various commonly employed MBBs are described below. Specifically, MBB entries for a pulley-belt mechanism are described below in conjunction with FIGS. 2A and 2B, MBB entries for a spur-gear mechanism are described below in conjunction with FIGS. 3A and 3B, MBB entries for a worm-gear mechanism are described below in conjunction with FIGS. 4A and 4B, MBB entries for a slider mechanism are described below in conjunction with FIGS. 5A and 5B, MBB entries for an L-linkage pivot are described below in conjunction with FIGS. 6A and 6B, and MBB entries for a four-bar linkage are described below in conjunction with FIGS. 7A and 7B.

FIG. 2A is a schematic illustration 200 of a pulley-belt mechanism that can be an MBB referenced in MBB library 130, according to various embodiments. In some embodiments, schematic illustration 200 can be included as an entry in MBB library 130 that is associated with the pulley-belt mechanism MBB. For example, schematic illustration 200 can be displayed by UI 110 in FIG. 1 to facilitate user interactions with mechanical system optimization engine 100 when selecting MBBs to include in a mechanical system and/or when providing inputs 112 associated with the pulley-belt mechanism MBB.

Schematic illustration 200 depicts geometrical and/or physical attributes of a pulley-belt mechanism that are pertinent to and/or referenced by a dynamic equation associated with the pulley-belt mechanism MBB referenced in MBB library 130. Thus, in the embodiment illustrated in FIG. 2A, schematic illustration 200 includes an input torque T₁, an output torque T₂, a radius r₁ of an output pulley wheel and a radius r₂ of an output pulley wheel. In the embodiment illustrated in FIG. 2A, radius r₁ and radius r₂ are design variables for the pulley-belt mechanism MBB, and values for these design variables are determined by mechanical system optimization engine 100 during an optimization process as described below. In other embodiments, additional design variables may be associated with the pulley-belt mechanism MBB. In the embodiment illustrated in FIG. 2A, input torque T₁, output torque T₂, radius r₁ and radius r₂ are referenced in other entries in MBB library 130 that are associated with the pulley-belt mechanism MBB. Examples of such entries are described below in conjunction with FIG. 2B.

FIG. 2B illustrates entries 250 in MBB library 130 that are associated with the pulley-belt mechanism MBB referenced in MBB library 130. In the embodiment illustrated in FIG. 2B, entries 250 include classification information 251, input information 252, output information 253, geometrical information 254, and a dynamic equation 255. In other embodiments, additional entries may be included for some or all MBBs referenced in MBB library 130.

Classification information 251 classifies the foundation information of the pulley-belt mechanism MBB. In the embodiment illustrated in FIG. 2B, classification information 251 includes data about input motion, output motion, a relative angle of the mechanical input and mechanical output (perpendicular or parallel), and speed information. Input information 252 indicates the input variables (I=) for the pulley-belt mechanism MBB and output information 253 indicates the output variables (O=) for the pulley-belt mechanism MBB. Geometrical information 254 indicates, for some MBBs, applicable geometrical information or clarification notes pertaining to the pulley-belt mechanism MBB. Dynamic equation 255 provides the equation to obtain appropriate position, velocity, acceleration (where applicable), and/or force/torque values for the pulley-belt mechanism MBB. In some embodiments, for more complex MBBs, dynamic equation 255 is implemented as a system of equations, such as in the case of a four-bar linkage (described below in conjunction with FIGS. 7A and 7B).

FIG. 3A is a schematic illustration 300 of a spur-gear mechanism that can be an MBB referenced in MBB library 130, according to various embodiments. In some embodiments, schematic illustration 300 can be included as an entry in MBB library 130 that is associated with the spur-gear mechanism MBB, and otherwise can be consistent with schematic illustration 200 in FIG. 2A. For example, schematic illustration 300 can be displayed by UI 110 in FIG. 1 to facilitate user interactions with mechanical system optimization engine 100 when selecting MBBs to include in a mechanical system and/or when providing inputs 112 associated with the spur-gear mechanism MBB.

FIG. 3B illustrates entries 350 in MBB library 130 that are associated with the spur-gear mechanism MBB referenced in MBB library 130. Entries 350 can be consistent with entries 250 in FIG. 2B, except for MBB-specific information included therein. For example, in the embodiment illustrated in FIG. 3B, entries 350 include classification information 351, input information 352, output information 353, geometrical information 354, and a dynamic equation 355.

FIG. 4A is a schematic illustration 400 of a worm-gear mechanism that can be an MBB referenced in MBB library 130, according to various embodiments. In some embodiments, schematic illustration 400 can be included as an entry in MBB library 130 that is associated with the worm-gear mechanism MBB, and otherwise can be consistent with schematic illustration 200 in FIG. 2A. For example, schematic illustration 400 can be displayed by UI 110 in FIG. 1 to facilitate user interactions with mechanical system optimization engine 100 when selecting MBBs to include in a mechanical system and/or when providing inputs 112 associated with the worm-gear mechanism MBB.

FIG. 4B illustrates entries 450 in MBB library 130 that are associated with the worm-gear mechanism MBB referenced in MBB library 130. Entries 450 can be consistent with entries 250 in FIG. 2B, except for MBB-specific information included therein. For example, in the embodiment illustrated in FIG. 4B, entries 450 include classification information 451, input information 452, output information 453, geometrical information 454, and a dynamic equation 455.

FIG. 5A is a schematic illustration 500 of a slider mechanism that can be an MBB referenced in MBB library 130, according to various embodiments. In some embodiments, schematic illustration 500 can be included as an entry in MBB library 130 that is associated with the slider mechanism MBB, and otherwise can be consistent with schematic illustration 200 in FIG. 2A. For example, schematic illustration 500 can be displayed by UI 110 in FIG. 1 to facilitate user interactions with mechanical system optimization engine 100 when selecting MBBs to include in a mechanical system and/or when providing inputs 112 associated with the slider mechanism MBB.

FIG. 5B illustrates entries 550 in MBB library 130 that are associated with the slider mechanism MBB referenced in MBB library 130. Entries 550 can be consistent with entries 250 in FIG. 2B, except for MBB-specific information included therein. For example, in the embodiment illustrated in FIG. 5B, entries 550 include classification information 551, input information 552, output information 553, geometrical information 554, and a system of multiple dynamic equations 555.

FIG. 6A is a schematic illustration 600 of a L-linkage pivot that can be an MBB referenced in MBB library 130, according to various embodiments. In some embodiments, schematic illustration 600 can be included as an entry in MBB library 130 that is associated with the L-linkage pivot MBB, and otherwise can be consistent with schematic illustration 200 in FIG. 2A. For example, schematic illustration 600 can be displayed by UI 110 in FIG. 1 to facilitate user interactions with mechanical system optimization engine 100 when selecting MBBs to include in a mechanical system and/or when providing inputs 112 associated with the L-linkage pivot MBB.

FIG. 6B illustrates entries 650 in MBB library 130 that are associated with the L-linkage pivot MBB referenced in MBB library 130. Entries 650 can be consistent with entries 250 in FIG. 2B, except for MBB-specific information included therein. For example, in the embodiment illustrated in FIG. 6B, entries 650 include classification information 651, input information 652, output information 653, and a dynamic equation 655.

FIG. 7A is a schematic illustration 700 of a four-bar-linkage that can be an MBB referenced in MBB library 130, according to various embodiments. In some embodiments, schematic illustration 700 can be included as an entry in MBB library 130 that is associated with the four-bar-linkage MBB, and otherwise can be consistent with schematic illustration 200 in FIG. 2A. For example, schematic illustration 700 can be displayed by UI 110 in FIG. 1 to facilitate user interactions with mechanical system optimization engine 100 when selecting MBBs to include in a mechanical system and/or when providing inputs 112 associated with the four-bar-linkage MBB.

FIG. 7B illustrates entries 750 in MBB library 130 that are associated with the four-bar-linkage MBB referenced in MBB library 130. Entries 750 can be consistent with entries 250 in FIG. 2B, except for MBB-specific information included therein. For example, in the embodiment illustrated in FIG. 7B, entries 750 include classification information 751, input information 752, output information 753, geometrical information 754, and a system of multiple dynamic equations 755.

Returning to FIG. 1, matrix set-up module 120 translates information associated with a specific mechanical system of interest into a format that enables optimization algorithm to generate one or more optimal or high-performing configuration of the mechanical system. For example, in some embodiments, for a mechanical system that includes multiple kinematically linked MBBs (as indicated by inputs 112), matrix-set-up module 120 generates a system matrix for the mechanical system that can be employed by optimization algorithm 140 to determine an optimal and/or high-performing configuration of the mechanical system.

In some embodiments, matrix set-up module 120 determines a set of dynamic equations for the mechanical system of interest based on information included in inputs 112, then constructs or generates a system matrix based on the set of dynamic equations. For example, in some embodiments, matrix set-up module 120 determines a dynamic equation for each MBB indicated in inputs 112 to be included in the mechanical system. In some embodiments, matrix set-up module 120 determines the dynamic equation for each MBB included in the mechanical system based on information stored in MBB library 130 and associated with the MBB, such as dynamic equation 255 in FIG. 2B.

Generally, the system matrix constructed by matrix set-up module 120 has a matrix size of N×M, where N is the number of MBB dynamic equations incorporated into the system matrix and M is the total number of state variables and design variables in the MBB dynamic equations incorporated into the system matrix. In some embodiments, a modular analysis and unified derivatives (MAUD) architecture is applied to the MBB dynamic equations to construct or generate the system matrix. The MAUD architecture is widely used for multidisciplinary design optimization (MDO) problems, and formulates the multidisciplinary model as a nonlinear system of equations. In other embodiments, matrix set-up module 120 can employ any other technically feasible approach to construct the system matrix.

In some embodiments, the system matrix corresponds to the Jacobian of the mechanical system as defined by the MBB dynamic equations of the mechanical system. The Jacobian includes the derivatives of the state variables with respect to one or more different variables, such as time.

Optimization algorithm 140 determines or generates a set of parametric values for the set of dynamic equations of the mechanical system via parametric optimization. The set of parametric values determined or generated by optimization algorithm 140 defines a specific configuration of the mechanical system. For example, in an embodiment, the set of parametric values includes a value for some or all design variables (e.g., link length, gear-tooth radius, pulley radius, worm-gear diametral pitch, etc.) for the MBBs included in the mechanical system. Taken together, the set of parametric values indicates an optimal overall solution or high-performing overall solution for the mechanical system of interest with respect to the one or more specific design objectives included in inputs 112. Thus, given an assembly of kinematically linked mechanical devices (including, for example, one or more pulleys, worm gears, spur gears, linkages, and/or the like) and one or more design objectives, optimization algorithm 140 determines an optimal or high-performing solution to a mechanical problem.

To determine or generate the set of parametric values for the MBB dynamic equations that form the system matrix, optimization algorithm 140 performs non-linear, gradient-based optimization by solving the system Jacobian matrix. Optimization algorithm 140 can include any technically feasible gradient-based optimization algorithm or algorithms for performing such gradient-based optimization. For example, in an embodiment, optimization algorithm 140 includes IPOPT (Interior Point Optimizer) for performing the large-scale nonlinear optimization typically employed to determine or generate the set of parametric values.

Typically, the dynamic equations associated with the MBBs included in a particular mechanical system include kinematic and/or time-dependent equations. As a result, to determine an optimal or high-performing solution, the rate of change of the state variables with respect to time is also considered by optimization algorithm 140, in addition to the sensitivity of the objective function with respect to the design variables. Consequently, in some embodiments, optimization algorithm 140 discretizes the dynamic equations associated with the MBBs. For example, in some embodiments, optimization algorithm 140 employs the well-known collocation method, which is a direct optimization method based on an implicit integration technique. Collocation involves approximating a system's responses at several points (collocation points) within a design space. By analyzing these points, optimization algorithm 140 can predict behavior of the mechanical system across the entire design space, enhancing the accuracy and efficiency of the optimization algorithm 140. Thus, in such embodiments, the system matrix has a matrix size of N×(M×t), where t is the number of discrete collocation points.

### Parametric Optimization of a Mechanical System

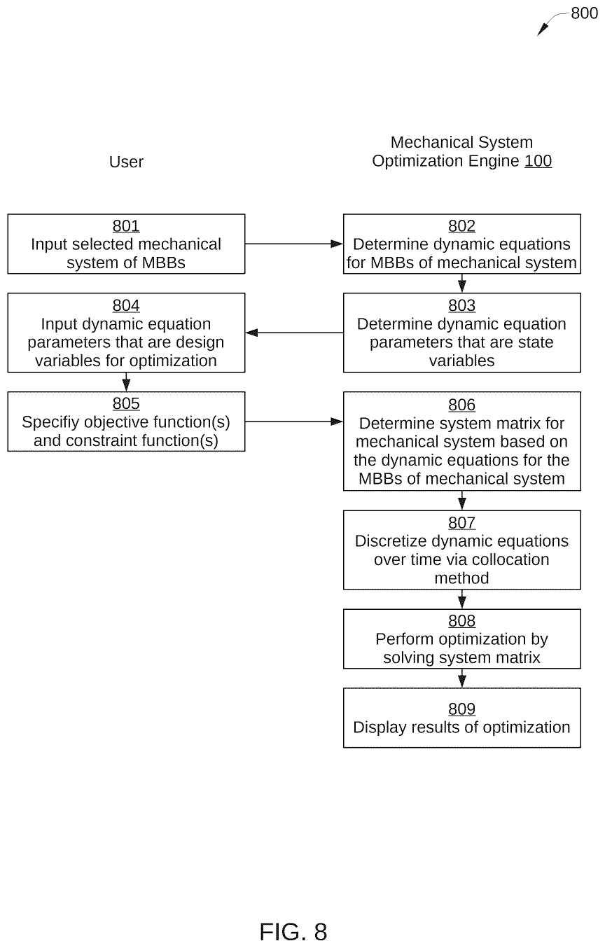

FIG. 8 sets forth a flowchart of method steps for selecting a configuration of a mechanical system that includes a plurality of mechanical building blocks, according to various embodiments. Although the method steps are described in conjunction with the system of FIG. 1, persons skilled in the art will understand that any suitable system configured to perform the method steps, in any order, is within the scope of the embodiments.

A computer-implemented method 800 begins at step 801, where a user inputs two or more MBBs that form a mechanical system. For example, in some embodiments, the user provides inputs 112 to UI 110 indicating two or more MBBs and how the MBBs are kinematically linked. Alternatively, the mechanical system of kinematically linked MBBs can be provided automatically, for example via a mechanical system design application, a machine-learning-based design application, or other software application.

In step 802, mechanical system optimization engine 100 determines the applicable dynamic equations for the MBBs of the mechanical system input in step 801, for example via matrix set-up module 120. In some embodiments, based on input 112, matrix set-up module 120 determines the applicable dynamic equations for each MBB in the mechanical system of interest based on entries in MBB library 130 that are associated with each MBB, such as entries 250 in FIG. 2B. In step 803, mechanical system optimization engine 100 determines the parameters of the dynamic equations for each MBB that is a state variable, such as rotational or translational velocity of a joint or link, displacement of a joint along a particular axis of translation, input torque to an MBB, output torque from an MBB, and the like. In some embodiments, the state variables for each MBB that is referenced in MBB library 130 can be stored in MBB library 130 prior to method 800.

In step 804, a user inputs dynamic equation parameters that are design variables to be optimized, for example via inputs 112. Generally, each design variable corresponds to an attribute or feature of an MBB included in the mechanical system, such as link length, gear-tooth radius, pulley radius, worm-gear diametral pitch, screw pitch angle, and the like. Taken together, the design variables describe the various configurations of the mechanical system that are possible to be implemented. In some embodiments, the user is prompted for entry of the design variables via UI 110.

In step 805, a user inputs one or more design objectives or objective functions, for example via inputs 112. For example, in some embodiments, an objective function is associated with a specific design requirement or combination of design requirements for the mechanical system. In some embodiments, in step 805 the user also inputs one or more constraint values or constrain functions for the mechanical system of interest, for example via inputs 112. Examples of such design constraints include maximum or minimum values for certain state variables of the mechanical system of interest and maximum or minimum values for certain design variables of the mechanical system of interest.

In step 806, mechanical system optimization engine 100 determines a system matrix based on the set of dynamic equations determined in step 802, for example via matrix set-up module 120. In some embodiments, matrix set-up module 120 determines a dynamic equation or system of dynamic equations for each MBB indicated in inputs 112 to be included in the mechanical system.

In step 807, mechanical system optimization engine 100 discretizes the system matrix over time, for example via optimization algorithm 140. In some embodiments, optimization algorithm 140 employs a collocation method in step 807.

In step 808, mechanical system optimization engine 100 solves the system matrix, via an optimization process, to determine or generate a set of parametric values for the set of dynamic equations. In some embodiments, mechanical system optimization engine 100 employs parametric optimization. The set of parametric values is associated with a specific mechanical configuration of the mechanical system that has optimal or high performance with respect to the one or more design objectives input in step 805.

In step 809, mechanical system optimization engine 100 displays the results of the optimization process performed in step 808, for example via output 114.

### Exemplary Case Study

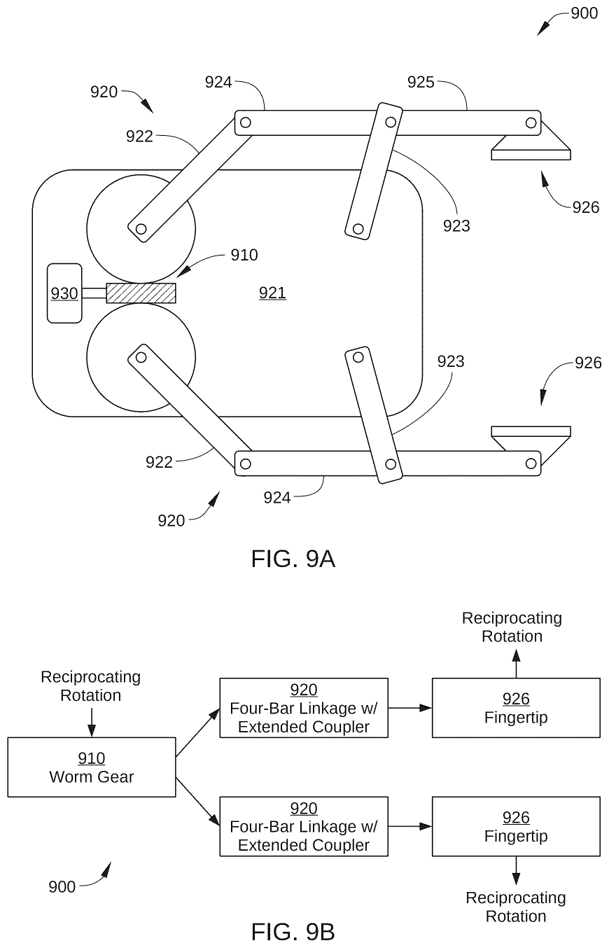

FIG. 9A is a schematic diagram of a mechanical system 900 that can be optimized, according to various embodiments. FIG. 9B is a block diagram illustrating the MBBs that are kinematically linked together to form mechanical system 900. In operation, mechanical system 900 grasps an object (not shown) given certain clearances and the position of the object. As shown in FIG. 9B, reciprocating rotation (e.g., of a motor 930) causes an output reciprocating rotation of fingertips 926.

In the embodiment illustrated in FIG. 9, mechanical system 900 is implemented as a gripper assembly, which is widely used for various tasks in many different industries. As shown, mechanical system 900 includes three kinematically linked MBBs: worm-gear 910 and two four-bar linkages 920. Each four-bar linkage 920 includes bar 921 (fixed), 922, 923, and 924, where bar 924 includes an extended coupler 925 with fingertip 926 disposed thereon for gripping with a reciprocating rotational motion. In some embodiments, the lengths thereof are design variables for the optimization problem. Alternatively, or additionally, in some embodiments, worm radius and gear radius of worm-gear 910 are design variables for the optimization problem. In an example embodiment, the cross-sections of bars 921, 922, 923, and 924 are considered constant, bars 921, 922, 923, and 924 are composed of a specified material, and a specific rotational speed and torque are assumed for motor 330.

In some embodiments, the optimization objective can be, for example, to minimize the time to grasp the object given certain constraints, to minimize a weight of mechanical system 900, and/or to maximize lifting capacity of mechanical system 900, among others. Because mechanical system 900 is broken down via a modular approach into multiple MBBs, equations can be added for a specific module, to define optimization objectives, and/or to apply various constraints on the problem. An example of such a constraint includes a range within with the length of each of bars 921, 922, 923, and 924 can vary (e.g., +20% to −20% of some initial value) and/or a maximum weight of mechanical system 900. Equations can be employed that define force at fingertip 926, distance traveled by fingertip 926 in the x-direction (for example as a function of the length and angle of certain bars of four-bar linkage 920), distance traveled by fingertip 926 in the y-direction (for example as a function of the length and angle of certain bars of four-bar linkage 920), weight of each four-bar linkage 920, and the objective function of the study.

### Exemplary Computing Device

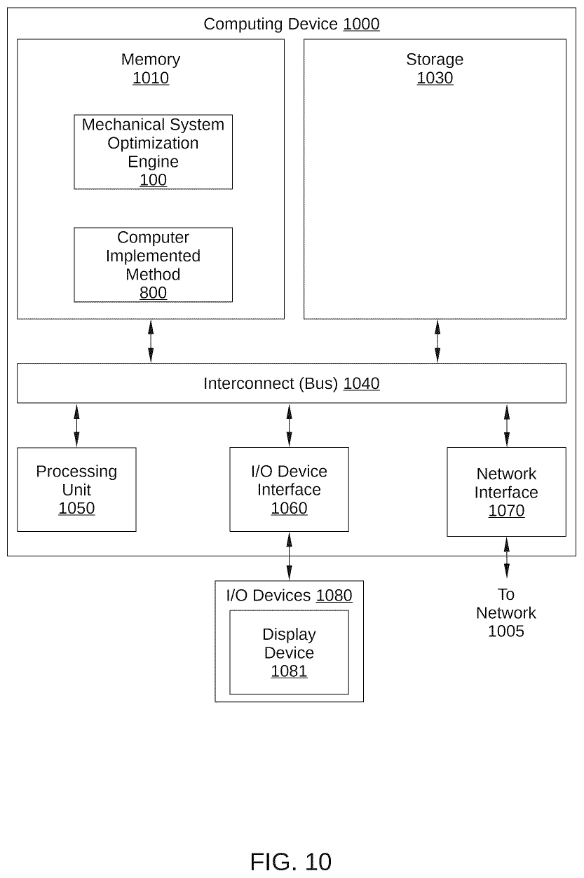

FIG. 10 is a block diagram of a computing device 1000 configured to implement one or more aspects of the various embodiments. Thus, computing device 1000 can be a computing device associated with mechanical system optimization engine 100. Computing device 1000 may be a desktop computer, a laptop computer, a tablet computer, or any other type of computing device configured to receive input, process data, generate control signals, and display images. Computing device 1000 is configured to perform operations associated with mechanical system optimization engine 100, computer-implemented method 800, and/or other suitable software applications, which can reside in a memory 1010. It is noted that the computing device described herein is illustrative and that any other technically feasible configurations fall within the scope of the present disclosure.

As shown, computing device 1000 includes, without limitation, an interconnect (bus) 1040 that connects a processing unit 1050, an input/output (I/O) device interface 1060 coupled to input/output (I/O) devices 1080, memory 1010, a storage 1030, and a network interface 1070. Processing unit 1050 may be any suitable processor implemented as a central processing unit (CPU), a graphics processing unit (GPU), an application-specific integrated circuit (ASIC), a field programmable gate array (FPGA), any other type of processing unit, or a combination of different processing units, such as a CPU configured to operate in conjunction with a GPU. In general, processing unit 1050 may be any technically feasible hardware unit capable of processing data and/or executing software applications, including processes associated with mechanical system optimization engine 100 and/or computer-implemented method 800. Further, in the context of this disclosure, the computing elements shown in computing device 1000 may correspond to a physical computing system (e.g., a system in a data center) or may be a virtual computing instance executing within a computing cloud.

I/O devices 1080 may include devices capable of providing input, such as a keyboard, a mouse, a touch-sensitive screen, and so forth, as well as devices capable of providing output, such as a display device 1081. Additionally, I/O devices 1080 may include devices capable of both receiving input and providing output, such as a touchscreen, a universal serial bus (USB) port, and so forth. I/O devices 1080 may be configured to receive various types of input from an end-user of computing device 1000, and to also provide various types of output to the end-user of computing device 1000, such as one or more graphical user interfaces (GUI), displayed digital images, and/or digital videos. In some embodiments, one or more of I/O devices 1080 are configured to couple computing device 1000 to a network 1005.

Memory 1010 may include a random access memory (RAM) module, a flash memory unit, or any other type of memory unit or combination thereof. Processing unit 1050, I/O device interface 1060, and network interface 1070 are configured to read data from and write data to memory 1010. Memory 1010 includes various software programs that can be executed by processor 1050 and application data associated with said software programs, including mechanical system optimization engine 100 and/or computer-implemented method 800.

In sum, the various embodiments described herein provide techniques for making an assembly from modular units (MBBs), simulating the assembly, and conducting parametric optimization on the modular units. These MBBs can correspond to widely used mechanical device employed in industry for assembling mechanical systems. In the embodiments, a library of MBBs can be assembled to form different mechanical systems. Dynamic equations associated with each MBB of the mechanical system are used to construct a system matrix that enables parametric optimization of the mechanical system, where the design variables of each MBB correspond to an optimized parameter.

At least one technical advantage of the disclosed techniques relative to the prior art is that the disclosed techniques enable automated parametric optimization of a multi-device mechanical system with respect to one or more design objectives. As a result, for a mechanical system that includes an assembly of multiple kinematically linked mechanical devices, the effectiveness of a plurality of different configurations of the assembly can be quantitatively determined. The effectiveness of each of the different configurations can be determined based on multiple design objectives, and, in some embodiments, multi-disciplinary design objectives. As a result, for a mechanical system that addresses a complex and multi-disciplinary mechanical problem, the disclosed techniques can determine a configuration that corresponds to a global (multi-disciplinary) optimum. These technical advantages provide one or more technological advancements over prior art approaches.

1. In some embodiments, a computer-implemented method for selecting a configuration of a mechanical system that includes a plurality of mechanical building blocks includes: determining a set of dynamic equations for the mechanical system, wherein each dynamic equation included in the set of dynamic equations corresponds to one mechanical building block included in the plurality of mechanical building blocks; generating a system matrix for the mechanical system based on the set of dynamic equations; and generating a set of parametric values for the set of dynamic equations via parametric optimization, wherein the set of parametric values is associated with a specific configuration of the mechanical system.

2. The computer-implemented method of clause 1, wherein the parametric optimization comprises gradient-based optimization.

3. The computer-implemented method of clauses 1 or 2, wherein each parametric value in the set of parametric values corresponds to a design variable of at least one of the mechanical building blocks.

4. The computer-implemented method of any of clauses 1-3, wherein each mechanical building block included in the plurality of mechanical building blocks comprises a component of the mechanical system that is kinematically linked to at least one other component of the mechanical system.

5. The computer-implemented method of any of clauses 1-4, wherein each mechanical building block included in the plurality of mechanical building blocks corresponds to a mechanical device that generates a mechanical output in response to receiving a mechanical input.

6. The computer-implemented method of any of clauses 1-5, wherein each mechanical building block included in the plurality of mechanical building blocks comprises one of a four-bar linkage, a slider linkage of a first type, a slider linkage of a second type, a linkage pivot, a spur gear, a pulley belt, a worm gear, or a slider-bar.

7. The computer-implemented method of any of clauses 1-6, wherein the parametric optimization is performed based on one or more design objectives.

8. The computer-implemented method of any of clauses 1-7, wherein the set of parametric values corresponds to a global optimum of the one or more design objectives.

9. The computer-implemented method of any of clauses 1-8, wherein the set of parametric values for the set of dynamic equations are determined based at least in part on a constraint value.

10. The computer-implemented method of any of clauses 1-9, wherein the constraint value comprises a value associated with one of a state variable of the mechanical system or a design variable of the mechanical system.

11. The computer-implemented method of any of clauses 1-10, wherein the plurality of mechanical building blocks comprises a kinematic chain that generates a mechanical output in response to receiving a mechanical input.

12. In some embodiments, a non-transitory computer readable medium includes a set of instructions which, in response to execution by a processor of a computer system, cause the processor to perform the steps of: determining a set of dynamic equations for a mechanical system that includes a plurality of mechanical building blocks, wherein each dynamic equation included in the set of dynamic equations corresponds to one mechanical building block included in the plurality of mechanical building blocks; generating a system matrix for the mechanical system based on the set of dynamic equations; and generating a set of parametric values for the set of dynamic equations via parametric optimization, wherein the set of parametric values is associated with a specific configuration of the mechanical system.

13. The non-transitory computer readable medium of clause 12, wherein the parametric optimization comprises gradient-based optimization.

14. The non-transitory computer readable medium of clauses 12 or 13, wherein each parametric value in the set of parametric values corresponds to a design variable of at least one of the mechanical building blocks.

15. The non-transitory computer readable medium of any of clauses 12-14, wherein each mechanical building block included in the plurality of mechanical building blocks comprises a component of the mechanical system that is kinematically linked to at least one other component of the mechanical system.

16. The non-transitory computer readable medium of any of clauses 12-15, wherein each mechanical building block included in the plurality of mechanical building blocks corresponds to a mechanical device that generates a mechanical output in response to receiving a mechanical input.

17. The non-transitory computer readable medium of any of clauses 12-16, wherein each mechanical building block included in the plurality of mechanical building blocks comprises one of a four-bar linkage, a slider linkage of a first type, a slider linkage of a second type, a linkage pivot, a spur gear, a pulley belt, a worm gear, or a slider-bar.

18. The non-transitory computer readable medium of any of clauses 12-17, wherein the parametric optimization is performed based on one or more design objectives.

19. The non-transitory computer readable medium of any of clauses 12-18, wherein the set of parametric values corresponds to a global optimum of the one or more design objectives.

20. In some embodiments a system includes: a memory that stores instructions; and a processor that is communicatively coupled to the memory and is configured to, when executing the instructions, perform the steps of: determining a set of dynamic equations for a mechanical system that includes a plurality of mechanical building blocks, wherein each dynamic equation included in the set of dynamic equations corresponds to one mechanical building block included in the plurality of mechanical building blocks; generating a system matrix for the mechanical system based on the set of dynamic equations; and generating a set of parametric values for the set of dynamic equations via parametric optimization, wherein the set of parametric values is associated with a specific configuration of the mechanical system.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for selecting a configuration of a mechanical system that includes a plurality of mechanical building blocks, the method comprising:
determining a set of dynamic equations for the mechanical system, wherein each dynamic equation included in the set of dynamic equations corresponds to one mechanical building block included in the plurality of mechanical building blocks;
generating a system matrix for the mechanical system based on the set of dynamic equations; and
generating a set of parametric values for the set of dynamic equations via parametric optimization, wherein the set of parametric values is associated with a specific configuration of the mechanical system.

2. The computer-implemented method of claim 1, wherein the parametric optimization comprises gradient-based optimization.

3. The computer-implemented method of claim 1, wherein each parametric value in the set of parametric values corresponds to a design variable of at least one of the mechanical building blocks.

4. The computer-implemented method of claim 1, wherein each mechanical building block included in the plurality of mechanical building blocks comprises a component of the mechanical system that is kinematically linked to at least one other component of the mechanical system.

5. The computer-implemented method of claim 1, wherein each mechanical building block included in the plurality of mechanical building blocks corresponds to a mechanical device that generates a mechanical output in response to receiving a mechanical input.

6. The computer-implemented method of claim 1, wherein each mechanical building block included in the plurality of mechanical building blocks comprises one of a four-bar linkage, a slider linkage of a first type, a slider linkage of a second type, a linkage pivot, a spur gear, a pulley belt, a worm gear, or a slider-bar.

7. The computer-implemented method of claim 1, wherein the parametric optimization is performed based on one or more design objectives.

8. The computer-implemented method of claim 7, wherein the set of parametric values corresponds to a global optimum of the one or more design objectives.

9. The computer-implemented method of claim 1, wherein the set of parametric values for the set of dynamic equations are determined based at least in part on a constraint value.

10. The computer-implemented method of claim 9, wherein the constraint value comprises a value associated with one of a state variable of the mechanical system or a design variable of the mechanical system.

11. The computer-implemented method of claim 1, wherein the plurality of mechanical building blocks comprises a kinematic chain that generates a mechanical output in response to receiving a mechanical input.

12. A non-transitory computer readable medium that includes a set of instructions which, in response to execution by a processor of a computer system, cause the processor to perform the steps of:
determining a set of dynamic equations for a mechanical system that includes a plurality of mechanical building blocks, wherein each dynamic equation included in the set of dynamic equations corresponds to one mechanical building block included in the plurality of mechanical building blocks;
generating a system matrix for the mechanical system based on the set of dynamic equations; and
generating a set of parametric values for the set of dynamic equations via parametric optimization, wherein the set of parametric values is associated with a specific configuration of the mechanical system.

13. The non-transitory computer readable medium of claim 12, wherein the parametric optimization comprises gradient-based optimization.

14. The non-transitory computer readable medium of claim 12, wherein each parametric value in the set of parametric values corresponds to a design variable of at least one of the mechanical building blocks.

15. The non-transitory computer readable medium of claim 12, wherein each mechanical building block included in the plurality of mechanical building blocks comprises a component of the mechanical system that is kinematically linked to at least one other component of the mechanical system.

16. The non-transitory computer readable medium of claim 12, wherein each mechanical building block included in the plurality of mechanical building blocks corresponds to a mechanical device that generates a mechanical output in response to receiving a mechanical input.

17. The non-transitory computer readable medium of claim 12, wherein each mechanical building block included in the plurality of mechanical building blocks comprises one of a four-bar linkage, a slider linkage of a first type, a slider linkage of a second type, a linkage pivot, a spur gear, a pulley belt, a worm gear, or a slider-bar.

18. The non-transitory computer readable medium of claim 12, wherein the parametric optimization is performed based on one or more design objectives.

19. The non-transitory computer readable medium of claim 18, wherein the set of parametric values corresponds to a global optimum of the one or more design objectives.

20. A system, comprising:
a memory that stores instructions; and
a processor that is communicatively coupled to the memory and is configured to, when executing the instructions, perform the steps of:
determining a set of dynamic equations for a mechanical system that includes a plurality of mechanical building blocks, wherein each dynamic equation included in the set of dynamic equations corresponds to one mechanical building block included in the plurality of mechanical building blocks;
generating a system matrix for the mechanical system based on the set of dynamic equations; and
generating a set of parametric values for the set of dynamic equations via parametric optimization, wherein the set of parametric values is associated with a specific configuration of the mechanical system.
